(19) United States
(12) Patent Application Publication
(10) Pub. No.: US 2008/0178926 A1
(43) Pub. Date: Jul. 31, 2008

(54) ELECTRICITY GENERATION DEVICE USING SOLAR POWER

(76) Inventor: Ng Shun WU, Xiamen City (CN)

Correspondence Address: LEONG C LEI, PMB # 1008, 1867 YGNACIO VALLEY ROAD, WALNUT CREEK, CA, 94598, US

(21) Appl. No.: 11/743,679

(22) Filed: May 3, 2007

(30) Foreign Application Priority Data
Jan. 29, 2007 (CN) 200710008511.8

(51) Int. Cl. H01L 31/042

(52) U.S. Cl. 136/246

(57) ABSTRACT

The electricity generation device contains one or more photovoltaic members arranged into an array. Each photovoltaic member contains a solar cell and a reflection mirror. The solar cell is positioned above the reflection mirror with its light incidence plane facing downward towards the reflection mirror. The reflection mirror is formed by piecing a number of reflection plates side by side into a circular dish or by arranging a number of reflection dishes into a ring. The reflection plates or dishes are arranged so as to reflect the light beams towards the solar cell. The reflection mirror can also be an upside-down cone having slant inner surface or a dish having parabolic inner surface.

### TECHNICAL FIELD OF THE INVENTION

The present invention generally relates to electricity generation devices, and more particularly to an electricity generation device using solar power.

### DESCRIPTION OF THE PRIOR ART

Conventional electricity generation devices using solar power adopt a solar panel which is an assembly of photovoltaic or solar cells to transform solar power into electricity. To produce a large amount of electricity, the solar panel has to have a large area or a number of solar panels are pieced together into an array, so as to receive more solar power. In other words, a significant number of solar cells have to be employed, whose high cost inevitably limits the practical applications of these conventional electricity generation devices.

### SUMMARY OF THE INVENTION

Accordingly, a novel electricity generation device using solar power is provided herein to obviate the foregoing shortcomings of the prior arts.

The electricity generation device contains one or more photovoltaic members arranged into an array. Each photovoltaic member contains a solar cell and a reflection mirror. The solar cell is positioned above the reflection mirror with its light incidence plane facing downward towards the reflection mirror.

The reflection mirror is formed by piecing a number of reflection plates side by side into a circular dish or by arranging a number of reflection dishes into a ring. Each reflection plate or dish constitutes a sector of the circular reflection mirror subtending a central angle greater than 0 degree and less than 180 degrees. The reflection plates or dishes are arranged so as to reflect the light beams towards the solar cell. The reflection mirror can also be an upside-down cone having slant surface, or a dish having parabolic inner surface.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic diagram showing an electricity generation device according to a first embodiment of the present invention.

FIG. 2 is a perspective diagram showing a photovoltaic member of the electricity generation device of FIG. 1.

FIG. 3 is a profile diagram showing a photovoltaic member of the electricity generation device of FIG. 1.

FIG. 4 is a top-view diagram showing a photovoltaic member of an electricity generation device according to a second embodiment of the present invention.

FIG. 5 is a profile diagram showing a photovoltaic member of an electricity generation device according to a third embodiment of the present invention.

FIG. 6 is a perspective diagram showing a photovoltaic member of an electricity generation device according to a fourth embodiment of the present invention.

FIG. 7 is a profile diagram showing the photovoltaic member of FIG. 6.

FIG. 8 is a schematic diagram showing the operation principle of the reflection mirror of an electricity generation device according to the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

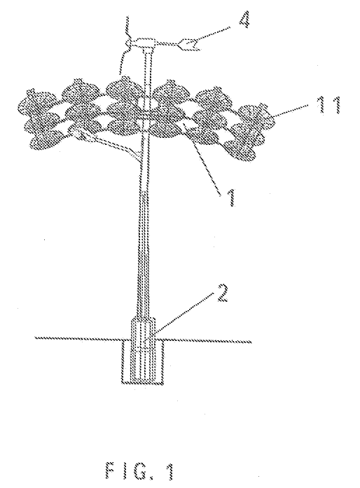

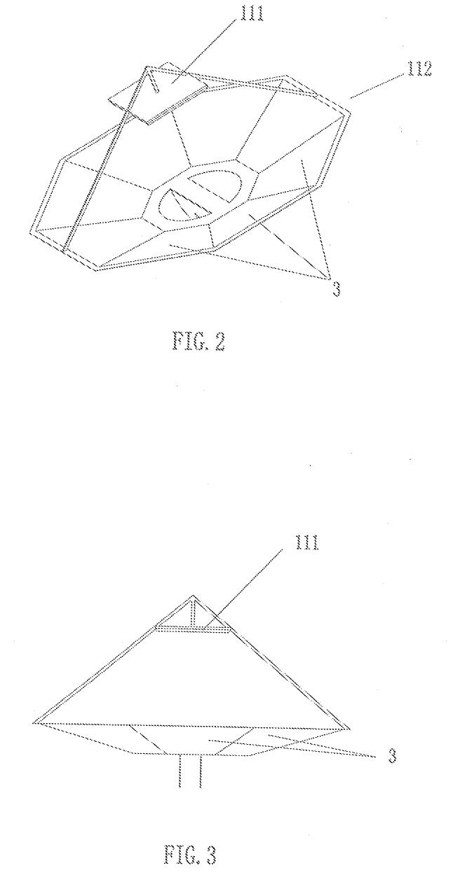

As shown in FIGS. 1 to 3, an electricity generation device according to a first embodiment of the present invention contains a solar power harness assembly 1 and a battery 2. The solar power harness assembly 1 in turn contains one or more photovoltaic members 11 arranged into an array. Each photovoltaic member 11 contains a solar cell 111 and a reflection mirror 112. The reflection mirror 112 is formed by piecing a number of reflection plates 3 side by side into a circular dish. Each reflection plate 3 constitutes a sector of the circular reflection mirror 112 subtending a central angle greater than 0 degree and less than 180 degrees. The solar cell 111 is positioned above the reflection mirror 112 with its light incidence plane facing downward towards the reflection mirror 112. Please note that the reflection plates 3 are tilted so as to reflect the light beams towards the solar cell 111. In other words a line connecting the solar cell 111 and a point on a reflection plate 3 is perpendicular to the reflection plate 3. As shown in the drawings, the present embodiment uses eight reflection plates 3 to form the reflection mirror 112, each subtending a central angle of 45 degrees. In an alternative embodiment, two reflection plates 3, each subtending a central angle of 180 degrees, are used to form the reflection mirror 112. In other words, the number of reflection plates 3 can be adapted to fit the particular sun lighting condition of the installation site such as the longitude and latitude, the season, whether there is blockage to the sun. For example, in places where the sunlight is weak, a larger number of reflection plates 3 can be adopted.

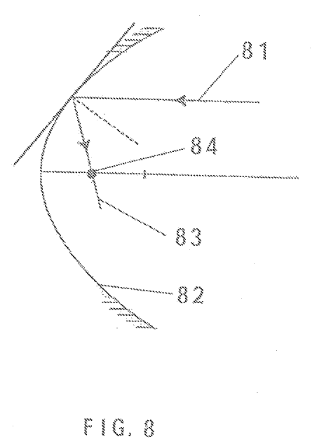

FIG. 8 is a schematic diagram showing the operation principle of the reflection mirror. Assuming that the reflection mirror has a parabolic inner surface 82, an incident light beam 81 parallel to the axis of the parabolic surface 82 is reflected by the inner surface 82 and the reflected light beam 83 passes through the focus 84 of the inner surface 82, where the solar cell is placed.

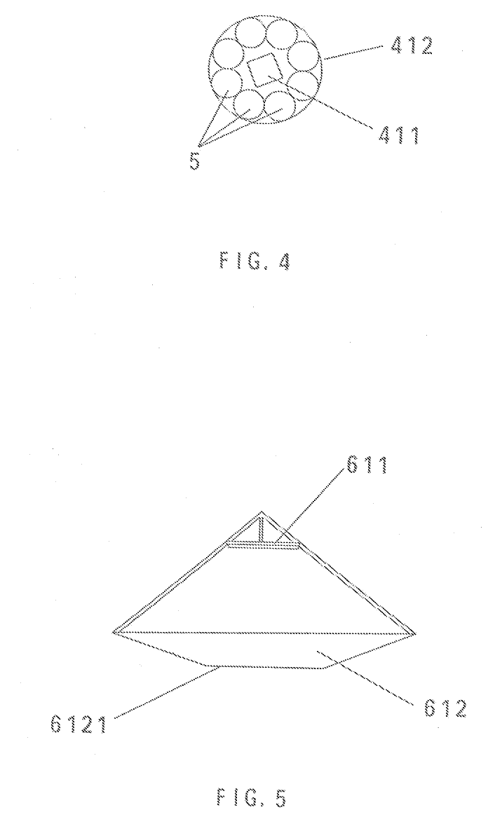

As shown in FIG. 4, in an electricity generation device according to a second embodiment of the present invention, each photovoltaic member 11 contains a solar cell 411 and a reflection 412. The reflection mirror 412 is formed by arranging a number of reflection dishes 5 into a circular ring. Each reflection dish 5 constitutes a sector of the circular reflection mirror 112 subtending a central angle greater than 0 degree and less than 180 degrees. The solar cell 411 is positioned the above the reflection mirror 412 with its light incidence plane facing downward towards the reflection mirror 412. Please note that the reflection dishes 5 are tilted so that their axes meet at where the solar cell 411 is located. As shown in the drawings, the present embodiment uses eight reflection dishes 5 to form the reflection mirror 412, each subtending a central angle of 45 degrees. Similar to the previous embodiment, the number of reflection dishes 5 can be adapted to fit the particular sun lighting condition of the installation site.

As shown in FIG. 5, in an electricity generation device according to a third embodiment of the present invention, each photovoltaic member 11 contains a solar cell 611 and a reflection mirror 612. The reflection mirror 612 is an upside-down cone with a through hole 6121 at the bottom so that rain will not accumulate inside the reflection mirror 612. Again, the slant inner surface of the conical reflection mirror 612 aims at the solar cell 611. In other words, a line connecting the solar cell 611 and a point on the inner surface of the reflection mirror 612 is perpendicular to the inner surface of the reflection mirror 612.

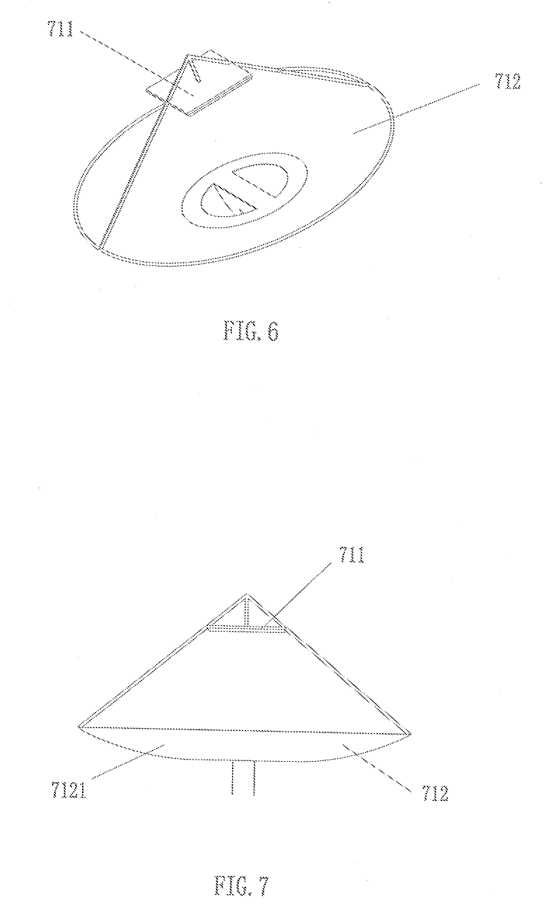

As shown in FIGS. 6 and 7, in an electricity generatiokn device according to a fourth embodiment of the present invention, each photovoltaic member 11 contains a solar cell 711 and a reflection mirror 712. The reflection mirror 712 is a dish with a through hole 7121 at the bottom so that rain will not accumulate inside the reflection mirror 712. Please note that the reflection mirror 712 is curved parabolically and the solar cell 711 is at the focus of the parabolic inner surface of the reflection mirror 712.

According to the foregoing description, the electricity generation device according to the present invention focuses sunlight beams on the solar cell and therefore only a limited number of solar cells are required. In addition, together by arranging a number of photovoltaic members 11 into an array and pointing the reflection mirrors 112 of the photovoltaic members 11 towards appropriate directions, respectively, the electricity generation device is able to make the best use of the sunlight without employing a large piece of solar panel yet delivering an even greater amount of electricity. The reflection plates or dishes can be made of a plastic material with a reflective electroplating coating, a stainless plate, a mirror, etc., driving the manufacturing cost of the electricity generation device even lower. Furthermore, the solar cells in the present invention are positioned up-side-down and therefore the dusts and bird droppings will not accumulate on the light incidence planes of the solar cells to affect their performance. To further protect the solar cell, a protective cover can be fixedly configured above the solar cell (not shown in the drawings). As shown in FIG. 1, the present invention can be further integrated with an electricity generation device 4 utilizing wind power to provide 24-hour, non-stop electricity generation.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An electricity generation device using solar power, comprising a first photovoltaic member having a solar cell and a reflection mirror; wherein
said solar cell is positioned above said reflection mirror with the light incidence plane facing downward towards said reflection mirror;
said reflection mirror comprises a plurality of reflection plates piecing side by side into a circular dish;
each of said reflection plate constitutes a sector of said reflection mirror subtending a central angle between 0 degree and less than 180 degree; and
a line connecting said solar cell and a point on a reflection plate is perpendicular to said reflection plate.

2. The electricity generation device according to claim 1, wherein said solar cell is positioned under a protective cover.

3. The electricity generation device according to claim 1, wherein said reflection plate is made of one of a plastic material with reflective coating, stainless steal, and a mirror.

4. The electricity generation device according to claim 1, further comprising at least a second photovoltaic member identically structured with said first photovoltaic member.

5. An electricity generation device using solar power, comprising a first photovoltaic member having a solar cell and a reflection mirror; wherein
said solar cell is positioned above said reflection mirror with the light incidence plane facing downward towards said reflection mirror;
said reflection mirror comprises a plurality of reflection dishes arranged into a circular ring;
each of said reflection dishes constitutes a sector of said reflection mirror subtending a central angle between 0 degree and less than 180 degree; and
the axes of said reflection dishes intersect at where said solar cell is located.

6. The electricity generation device according to claim 5, wherein said solar cell is positioned under a protective cover.

7. The electricity generation device according to claim 5, wherein said reflection dish is made of one of a plastic material with reflective coating, stainless steal, and a mirror.

8. The electricity generation device according to claim 5, further comprising at least a second photovoltaic member identically structured with said first photovoltaic member.

9. An electricity generation device using solar power, comprising a first photovoltaic member having a solar cell and a reflection mirror; wherein
said solar cell is positioned above said reflection mirror with the light incidence plane facing downward towards said reflection mirror; and
said reflection mirror is a dish curved parabolically having a through hole at the bottom and said solar cell located at the focus.

10. The electricity generation device according to claim 9, wherein said solar cell is positioned under a protective cover.

11. The electricity generation device according to claim 9, wherein said reflection mirror is made of one of a plastic material with reflective coating, stainless steal, and a mirror.

12. An electricity generation device using solar power, comprising a first photovoltaic member having a solar cell and a reflection mirror; wherein
said solar cell is positioned above said reflection mirror with the light incidence plane facing downward towards said reflection mirror;
said reflection mirror is an up-side-down cone having a through hole at the bottom; and
a line connecting said solar cell and a point on the slant inner surface of said reflection mirror is perpendicular to the slant inner surface of said reflection mirror.

13. The electricity generation device according to claim 12, wherein said solar cell is positioned under a protective cover.

14. The electricity generation device according to claim 12, wherein said reflection mirror is made of one of a plastic material with reflective coating, stainless steal, and a mirror.
